(19) United States
(12) Patent Application Publication
(10) Pub. No.: US 2023/0418150 A1
(43) Pub. Date: Dec. 28, 2023

(54) BLANK MASK AND PHOTOMASK USING THE SAME

(71) Applicant: SK enpulse Co., Ltd., Pyeongtaek-si (KR)

(72) Inventors: GeonGon LEE, Seoul (KR); Hyung-joo LEE, Seoul (KR); Suhyeon KIM, Seoul (KR); Sung Hoon SON, Seoul (KR); Seong Yoon KIM, Seoul (KR); Min Gyo JEONG, Seoul (KR); Taewan KIM, Seoul (KR); Inkyun SHIN, Seoul (KR); Tae Young KIM, Seoul (KR)

(73) Assignee: SK enpulse Co., Ltd., Pyeongtaek-si (KR)

(21) Appl. No.: 18/340,334

(22) Filed: Jun. 23, 2023

(30) Foreign Application Priority Data
Jun. 23, 2022 (KR) 10-2022-0076792

(51) Int. Cl. G03F 1/32

(52) U.S. Cl. CPC G03F 1/32

(57) ABSTRACT

A blank mask includes a light transmissive substrate, and a light-blocking layer, disposed on the light transmissive substrate, comprising a transition metal and either one or both of oxygen and nitrogen. An average value of grain sizes of a surface of the light-blocking layer ranges from 14 nm to 24 nm.

### CROSS-REFERENCE TO RELATED APPLICATION

This application claims the benefit under 35 USC § 119(a) of Korean Patent Application No. 10-2022-0076792, filed on Jun. 23, 2022, the entire disclosure of which is incorporated herein by reference for all purposes.

### BACKGROUND

### 1. Field

The following description relates to a blank mask and a photomask using the same.

### 2. Discussion of Related Art

Fine semiconductor circuit patterns may be desired due to the high integration of semiconductor devices. Thus, the importance of lithography, which is a technique for developing circuit patterns on the surface of a wafer using a photomask, is increasing.

In order to develop fine circuit patterns, short wavelengths of exposure light sources used in exposure processes may be desired. Recently, an ArF excimer laser (having a 193 nm wavelength) has been used as the exposure light source.

Meanwhile, photomasks include binary masks and phase shift masks.

A binary mask has a configuration in which a light-blocking layer pattern is formed on a light-transmissive substrate. In a surface of the binary mask on which a pattern is formed, a transmissive portion not including a light-blocking layer transmits exposure light, and a blocking portion including the light-blocking layer blocks the exposure light so that the pattern is exposed on a resist film on a surface of a wafer. However, as the pattern becomes finer, the binary mask may have a problem in the development of a fine pattern due to the diffraction of light generated from an edge of the transmissive portion during the exposure process.

The phase shift masks include Levenson-type phase shift masks, outrigger-type phase shift masks, and half-tone type phase shift masks. Among the phase shift masks, the half-tone type phase shift mask has a configuration in which a pattern is formed of a semi-transmissive layer on a light transmissive substrate. In a surface of the half-tone type phase shift mask on which a pattern is formed, a transmissive portion not including the semi-transmissive layer transmits exposure light, and a semi-transmissive portion including the semi-transmissive layer transmits attenuated exposure light. The attenuated exposure light has a phase difference compared to the exposure light passing through the transmissive portion. Thus, since diffracted light generated from an edge of the transmissive portion is offset by the exposure light passing through the semi-transmissive portion, the phase shift mask may form a more elaborate fine pattern on the surface of the wafer.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a blank mask includes a light transmissive substrate, and a light-blocking layer, disposed on the light transmissive substrate, comprising a transition metal and either one or both of oxygen and nitrogen. An average value of grain sizes of a surface of the light-blocking layer ranges from 14 nm to 24 nm.

A number of grains on the surface of the light-blocking layer may be 20 or more and 55 or less per 0.01 μm².

The light-blocking layer may further include a first light-blocking layer and a second light-blocking layer disposed on the first light-blocking layer, and an etching speed of the second light-blocking layer etched with argon gas may be 0.3 Å/s or more and 0.5 Å/s or less.

The light-blocking layer may include a first light-blocking layer and a second light-blocking layer disposed on the first light-blocking layer, and an etching speed of the first light-blocking layer etched with argon gas may be 0.56 Å/s or more.

An etching speed of the light-blocking layer etched with a chlorine-based gas may be 1.5 Å/s or more.

The transition metal may include Fe and any one or more among Cr, Ta, Ti, and Hf.

The light-blocking layer may be formed using a sputtering target including 0.0001 to 0.035 parts by weight of Fe based on a total of 100 parts by weight of the transition metal.

The light-blocking layer may further include a first light-blocking layer and a second light-blocking layer disposed on the first light-blocking layer, and the second light-blocking layer may include 40 at % or more and 70 at % or less transition metal.

In another general aspect, a photomask includes a light transmissive substrate, and a light-blocking pattern layer, disposed on the light transmissive substrate, comprising a transition metal and either one or both of oxygen and nitrogen. An average value of grain sizes of a surface of the light-blocking pattern layer ranges from 14 nm to 24 nm.

In another general aspect, a method of manufacturing a semiconductor device, includes selectively exposing light incident from a light source through a photomask to a semiconductor wafer on which a resist layer is deposited, and developing a pattern on the semiconductor wafer. The photomask includes a light transmissive substrate and a light-blocking pattern layer disposed on the light transmissive substrate. The light-blocking pattern layer includes a transition metal and either one or both of oxygen and nitrogen. An average value of grain sizes of a surface of the light-blocking pattern layer ranges from 14 nm to 24 nm.

The light-blocking layer may further include a plurality of light-blocking layers, and an etching speed of a topmost light-blocking layer of the plurality of light-blocking layers etched with argon gas may be 0.3 Å/s or more and 0.5 Å/s or less.

The light-blocking layer may further include a plurality of light-blocking layers, and an etching speed of an intermediate light-blocking layer of the plurality of light-blocking layers etched with argon gas may be 0.56 Å/s or more.

Other features and aspects will be apparent from the following detailed description, the drawings, and the claims.

### BRIEF DESCRIPTION OF THE DRAWINGS

FIG. 1 is a conceptual diagram for describing a blank mask according to one embodiment.

FIG. 2 is a conceptual diagram for describing a blank mask according to another embodiment.

FIG. 3 is a conceptual diagram for describing a blank mask according to still another embodiment.

FIG. 4 is a conceptual diagram for describing a photomask according to yet another embodiment.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

Throughout the present specification, the term “a combination thereof” included in an expression of a Markush form means a mixture or combination of one or more selected from the group consisting of components described in the expression of the Markush form and means including one or more selected from the group consisting of the above components.

Throughout the present specification, the description of “A and/or B” means “A, B, or A and B.”

As semiconductors become more highly integrated, patterned light-blocking layers may be desired to have narrower linewidths. However, as the linewidth of the designed pattern becomes narrower, it may become more difficult to precisely control the shape of a light-blocking pattern layer, and the occurrence frequency of defects in a pattern layer may increase.

Meanwhile, for fine patterns, a defect inspection set to high sensitivity is requested. However, when the high-sensitivity defect inspection is performed, there is a problem of degradation of accuracy of inspection results, such as the detection of many pseudo-defects in addition to actual defects. This causes a defective rate of a photomask to increase.

The pseudo-defects do not cause degradation in the resolution of the blank mask or photomask and thus do not correspond to actual defects, but it means that the pseudo-defects are determined as defects when inspected with a high-sensitivity defect inspection device.

The inventors of the embodiments have confirmed that, by controlling an average value of grain sizes on a surface of the light-blocking layer, it is possible to realize a high-resolution photomask and provide a blank mask in which it is easy to detect defects through a high-sensitivity defect inspection, and have completed the embodiments.

Hereinafter, the embodiments will be described in detail.

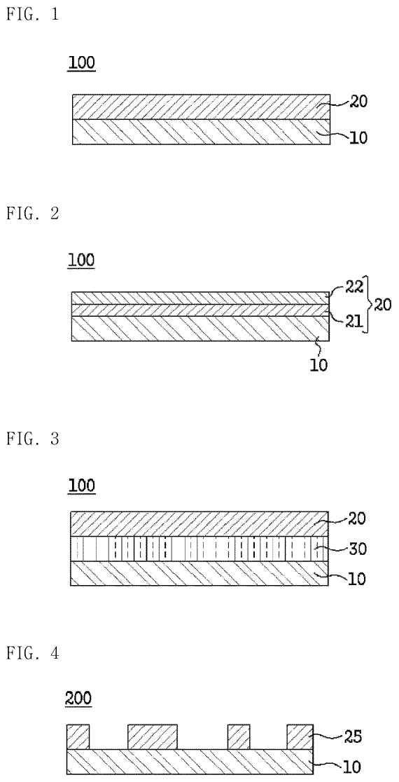

FIG. 1 is a conceptual diagram for describing a blank mask according to one embodiment. The blank mask of the embodiment will be described with reference to FIG. 1.

The blank mask 100 includes a light transmissive substrate 10 and a light-blocking layer 20 disposed on the light transmissive substrate 10.

A material of the light transmissive substrate 10 is not limited as long as the material has light transmissivity for exposure light and can be applied to the blank mask 100. Specifically, the transmittance of the light transmissive substrate 10 to exposure light with a 193 nm wavelength may be 85% or more. The transmittance may be 87% or more. The transmittance may be 99.99% or less. For example, a synthetic quartz substrate may be employed as the light transmissive substrate 10. In this case, the light transmissive substrate 10 may suppress the attenuation of light passing through the light transmissive substrate 10.

In addition, the occurrence of optical distortion in the light transmissive substrate 10 may be suppressed by adjusting surface characteristics such as flatness and roughness.

The light-blocking layer 20 may be positioned on a top side of the light transmissive substrate 10.

The light-blocking layer 20 may have a characteristic of blocking at least a portion of the exposure light incident on a bottom side of the light transmissive substrate 10. In addition, when a phase inversion layer 30 is positioned between the light transmissive substrate 10 and the light-blocking layer 20 (see FIG. 3), the light-blocking layer 20 may be used as an etch mask in a process of etching the phase inversion layer 30 according to a pattern shape.

The light-blocking layer 20 includes a transition metal and either one or both of oxygen and nitrogen.

Grain-related characteristics of the surface of light-blocking layer

An average value of grain sizes of a surface of the light-blocking layer 20 ranges from 14 nm to 24 nm.

A resist pattern layer may be formed by radiating an electron beam on a resist layer formed on the light-blocking layer 20. Recently, due to the miniaturization of semiconductor devices, photomasks applied to exposure processes have also come to have more miniaturized patterns and higher pattern densities. In order to realize such a photomask, a blank mask is exposed to an electron beam for a longer time than before. When the radiation of the electron beam continues, a charge-up phenomenon in which electrons are accumulated on the surface of the light-blocking layer 20 disposed below the resist layer may occur. When the electron beam is radiated onto the surface of the charged light-blocking layer, repulsion between electrons included in the electron beam and the electrons accumulated on the surface of the light-blocking layer may occur. Thus, difficulties may occur in controlling a precise shape of a resist pattern layer to be developed. In addition, the charged light-blocking layer may affect an inspector during a defect inspection and degrade the accuracy of the defect inspection.

According to the embodiment, the average value of the grain sizes of the transition metal on the surface of the light-blocking layer 20 may be controlled within a range set in the embodiment to control a crystal grain boundary density of the surface. In this way, since the electrons accumulated on the surface of the light-blocking layer 20 can move more freely within the light-blocking layer, the degree of charging of the surface of the light-blocking layer 20 can be effectively reduced. Simultaneously, since the crystal grain boundaries on the surface of the light-blocking layer are controlled, it is possible to prevent the etching speed of the light-blocking layer from being excessively lowered and prevent the roughness of the surface of the light-blocking layer from increasing to a predetermined level or more.

The average value of the grain sizes of the surface of the light-blocking layer 20 is measured through a secondary electron microscope (SEM). Specifically, the measurement magnification of the SEM is set to 150 k, a voltage to 5.0 kV, and a working distance (WD) (a distance between a lens and a sample) to 4 mm, and an image of the surface of the light-blocking layer is measured. The average value of the grain sizes of the surface of the light-blocking layer is measured from the image through an intercept method disclosed in ASTM E112-96e1.

A method of measuring the average value of the grain sizes through the intercept method is as follows. Four random lines with the same length are drawn on the image of the surface of the light-blocking layer 20. A crystal grain size D for each line is calculated according to the following Equation 1.

$$D = \frac{l}{n \times M} \qquad Equation 1$$

In Equation 1, D denotes the crystal grain size, I denotes the length of the line, n denotes the number of intersections between the line and the crystal grain boundaries of the surface of the light-blocking layer, and M denotes magnification applied to the SEM.

The calculated average value of the grain sizes is taken as an average value of the grain sizes of the surface of the light-blocking layer 20.

The average value of the grain sizes of the surface of the light-blocking layer 20 may range from 14 nm to 24 nm. The average value may be 15 nm or more. The average value may be 16 nm or more. The average value may be 17 nm or more. The average value may be 19 nm or more. The average value may be 23 nm or less. The average value may be 22 nm or less. In this case, a resist pattern layer with an excellent resolution may be formed on the light-blocking layer, and the accuracy of a defect inspection on the surface of the light-blocking layer can be effectively increased.

The number of grains on the surface of the light-blocking layer 20 may be 20 or more and 55 or less per 0.01 μm².

According to the embodiment, the number of grains per unit area on the surface of the light-blocking layer 20 may be controlled. In this way, since distribution of the crystal grain boundaries on the surface of the light-blocking layer 20 is controlled, the etching speed of the light-blocking layer 20 with respect to an etching gas can be suppressed from excessively decreasing. In addition, during the patterning process using the electron beam, the degree of electron repulsion occurring on the surface of the light-blocking layer 20 can be effectively reduced. In addition, the occurrence frequency of errors by the inspector due to the charging can be substantially reduced.

The number of grains per 0.01 μm² of the surface of the light-blocking layer is measured from the SEM image with an area of 1 μm horizontally and 1 μm vertically located on the surface of the light-blocking layer. Description of a method of measuring the SEM image of the surface of the light-blocking layer will be omitted because it overlaps the above description.

When the number of grains is calculated, grains located across one side of the area of 1 μm horizontally and 1 μm vertically are calculated as 0.5, and grains located across a corner of the area and only partially observed are calculated as 0.25.

The number of grains on the surface of the light-blocking layer 20 may be 20 or more and 55 or less per 0.01 μm². The number of grains on the surface of the light-blocking layer may be 25 or more per 0.01 μm². The number of grains on the surface of the light-blocking layer may be 30 or more per 0.01 μm². The number of grains on the surface of the light-blocking layer may be 52 or less per 0.01 μm². The number of grains on the surface of the light-blocking layer may be 50 or less per 0.01 μm². In these cases, it is possible to improve the etching speed of the light-blocking layer with respect to the etching gas, and it is possible to enable precise patterning of the light-blocking layer by applying a thinner resist layer on the light-blocking layer.

Etching Characteristics of the Light-Blocking Layer

FIG. 2 is a conceptual diagram for describing the blank mask according to one embodiment. The blank mask of the embodiment will be described with reference to FIG. 2.

The light-blocking layer 20 may include a first light-blocking layer 21 and a second light-blocking layer 22 disposed on the first light-blocking layer 21.

A measured etching speed of the second light-blocking layer 22 etched with argon (Ar) gas may be 0.3 Å/s or more and 0.5 Å/s or less.

The measured etching speed of the first light-blocking layer 21 etched with the Ar gas may be 0.56 Å/s or more.

According to the embodiment, the etching speed of each layer of the light-blocking layer 20 may be adjusted by controlling grain-related characteristics of each layer in the light-blocking layer 20. In this way, the etching speed of the light-blocking layer 20 with respect to an etching gas may be suppressed from being excessively lowered, and a side surface of the light-blocking pattern layer implemented from the light-blocking layer 20 through patterning may have a more vertical shape from a substrate surface.

In particular, according to the embodiment, it is possible to adjust the measured etching speed for each layer in the light-blocking layer 20 etched with the Ar gas. Dry etching performed by applying the Ar gas as an etchant corresponds to physical etching that does not involve a substantial chemical reaction between the etchant and the light-blocking layer 20. The etching speed measured using the Ar gas as an etchant is independent of the composition and chemical reactivity of each layer in the light-blocking layer 20 and is considered as a parameter that may effectively reflect a crystal grain boundary density of each layer.

A method of measuring the etching speed of the first light-blocking layer 21 and the second light-blocking layer 22 etched with Ar gas is as follows.

First, the thicknesses of the first light-blocking layer 21 and the second light-blocking layer 22 are measured using transmission electron microscopy (TEM). Specifically, a sample is prepared by processing a blank mask 100, which is a measurement target, into a size of 15 mm horizontally and 15 mm vertically. A surface of the sample is processed with a focused ion beam (FIB) and placed in a TEM image measuring instrument, and a TEM image of the sample is measured. The thicknesses of the first light-blocking layer 21 and the second light-blocking layer 22 are calculated from the TEM image. For example, the TEM image may be measured with a JEM-2100F HR model from JEOL Ltd.

Then, the first light-blocking layer 21 and the second light-blocking layer 22 of the sample are etched with Ar gas, and the time desired for etching each layer is measured. Specifically, the sample is placed in an X-ray photoelectron spectroscopy (XPS) measuring instrument, and an area of 4 mm horizontally and 2 mm vertically located in a central portion of the sample is etched with Ar gas to measure an etch time for each layer. When the etch time is measured, a vacuum level in the measuring instrument equipment is set to 1.0*10⁻⁸ mbar, an X-ray source is Monochromator Al Kα (1486.6 eV), anode power is set to 72 W, an anode voltage is set to 12 kV, and a voltage of an Ar ion beam is set to 1 kV. For example, a K-Alpha model from Thermo Fisher Scientific Inc. may be employed as the XPS measuring instrument.

From the measured thicknesses and etching times of the first light-blocking layer 21 and the second light-blocking layer 22, the measured etching speed of each layer etched with Ar gas is calculated.

The measured etching speed of the second light-blocking layer 22 etched with Ar gas may be 0.3 Å/s or more and 0.5 Å/s or less. The etching speed may be 0.35 Å/s or more. The etching speed may be 0.47 Å/s or less. The etching speed may be 0.45 Å/s or less. In these cases, it is possible to help more precisely control the shape of the patterned light-blocking layer 20 while preventing the etching speed of the light-blocking layer from excessively decreasing.

The measured etching speed of the first light-blocking layer 21 etched with the Ar gas may be 0.56 Å/s or more. The etching speed may be 0.58 Å/s or more. The etching speed may be 0.6 Å/s or more. The etching speed may be 1 Å/s or less. The etching speed may be 0.8 Å/s or less. In these cases, the exposure time of the second light-blocking layer to the etching gas may be reduced during the patterning process of the light-blocking layer.

According to the embodiment, it is possible to control the measured etching speed of the light-blocking layer 20 etched with a chlorine-based gas. In this way, the thickness of the resist layer desired for the patterning of the light-blocking layer 20 may be reduced. A resist pattern layer formed from the resist layer has a reduced aspect ratio so that a collapse phenomenon may be suppressed.

A method of measuring the etching speed of the light-blocking layer 20 with respect to a chlorine-based gas is as follows.

First, the TEM image of the light-blocking layer 20 is measured to measure the thickness of the light-blocking layer 20. The method of measuring the thickness of the light-blocking layer through TEM overlaps the above description, and thus description thereof will be omitted.

Thereafter, the light-blocking layer 20 is etched with a chlorine-based gas to measure an etching time. A gas containing 90 vol % to 95 vol % chlorine gas and 5 vol % to 10 vol % oxygen gas is employed as the chlorine-based gas. The etching speed of the light-blocking layer 20 with respect to the chlorine-based gas is calculated from the measured thickness and etching time of the light-blocking layer 20.

The measured etching speed of the light-blocking layer 20 etched with the chlorine-based gas may be 1.55 Å/s or more. The etching speed may be 1.6 Å/s or more. The etching speed may be 1.7 Å/s or more. The etching speed may be 3 Å/s or less. The etching speed may be 2 Å/s or less. In these cases, the patterning of the light-blocking layer 20 may be performed more precisely by forming the resist layer having a relatively thin thickness.

Composition of the Light-Blocking Layer

According to the embodiment, process conditions and the composition of the light-blocking layer 20 may be controlled in consideration of grain-related characteristics and etching characteristics desired for the light-blocking layer 20.

The content of each element for each layer of the light-blocking layer 20 may be confirmed by measuring a depth profile using XPS. Specifically, a sample is prepared by processing the blank mask 100 into a size of 15 mm horizontally and 15 mm vertically. Thereafter, the sample is placed in the XPS measuring equipment, and the content of each element for each layer is measured by etching an area of 4 mm horizontally and 2 mm vertically positioned in a central portion of the sample.

For example, the content of each element for each layer may be measured through K-alpha model from Thermo Fisher Scientific Inc.

The first light-blocking layer 21 may include 25 at % or more transition metal. The first light-blocking layer 21 may include 30 at % or more transition metal. The first light-blocking layer 21 may include 35 at % or more transition metal. The first light-blocking layer 21 may include 50 at % or less transition metal. The first light-blocking layer 21 may include 45 at % or less transition metal.

The first light-blocking layer 21 may include 30 at % or more oxygen. The first light-blocking layer 21 may include 35 at % or more oxygen. The first light-blocking layer 21 may include 55 at % or less oxygen. The first light-blocking layer 21 may include 50 at % or less oxygen. The first light-blocking layer 21 may include 45 at % or less oxygen.

The first light-blocking layer 21 may include 2 at % or more nitrogen. The first light-blocking layer 21 may include 5 at % or more nitrogen. The first light-blocking layer 21 may include 8 at % or more nitrogen. The first light-blocking layer 21 may include 25 at % or less nitrogen. The first light-blocking layer 21 may include 20 at % or less nitrogen. The first light-blocking layer 21 may include 15 at % or less nitrogen.

The first light-blocking layer 21 may include 2 at % or more carbon. The first light-blocking layer 21 may include 5 at % or more carbon. The first light-blocking layer 21 may include 10 at % or more carbon. The first light-blocking layer 21 may include 25 at % or less carbon. The first light-blocking layer 21 may include 20 at % or less carbon. The first light-blocking layer 21 may include 18 at % or less carbon.

These cases may help the light-blocking layer 20 to have excellent light extinction characteristics and may help the first light-blocking layer to have a relatively high etching speed compared to the second light-blocking layer.

The second light-blocking layer 22 may include 40 at % or more transition metal. The second light-blocking layer 22 may include 45 at % or more transition metal. The second light-blocking layer 22 may include 50 at % or more transition metal. The second light-blocking layer 22 may include 70 at % or less transition metal. The second light-blocking layer 22 may include 65 at % or less transition metal. The second light-blocking layer 22 may include 62 at % or less transition metal.

The second light-blocking layer 22 may include 5 at % or more oxygen. The second light-blocking layer 22 may include 8 at % or more oxygen. The second light-blocking layer 22 may include 10 at % or more oxygen. The second light-blocking layer 22 may include 35 at % or less oxygen. The second light-blocking layer 22 may include 30 at % or less oxygen. The second light-blocking layer 22 may include 25 at % or less oxygen.

The second light-blocking layer 22 may include 5 at % or more nitrogen. The second light-blocking layer 22 may include 8 at % or more nitrogen. The second light-blocking layer 22 may include 30 at % or less nitrogen. The second light-blocking layer 22 may include 25 at % or less nitrogen. The second light-blocking layer 22 may include 20 at % or less nitrogen.

The second light-blocking layer 22 may include 1 at % or more carbon. The second light-blocking layer 22 may include 4 at % or more carbon. The second light-blocking layer 22 may include 25 at % or less carbon. The second light-blocking layer 22 may include 20 at % or less carbon. The second light-blocking layer 22 may include 16 at % or less carbon.

These cases may help to reduce the degree of electron accumulation on the surface of the light-blocking layer due to the electron beam or light radiation.

The transition metal may include at least one among Cr, Ta, Ti, and Hf. The transition metal may include Cr. The transition metal may be Cr.

The transition metal may further include Fe.

When a small amount of Fe is further included in the light-blocking layer 20, a grain size may be controlled within a predetermined range during the thermal processing process. In particular, excessive growth of crystal grains in the light-blocking layer 20 may be suppressed even in the thermal processing process for a long period of time. This is considered to be caused by the fact that Fe acts as an impurity during the thermal processing process to hinder the continuous growth of crystal grains. According to the embodiment, by additionally applying Fe to the light-blocking layer 20, the grain-related characteristics, etching characteristics, and roughness characteristics of the light-blocking layer 20 may be controlled within a range set in the embodiment.

The light-blocking layer may be formed using a sputtering target including 0.0001 parts by weight or more of Fe and 0.035 parts by weight or less of Fe based on the total 100 parts by weight of the transition metal. The sputtering target may include 0.003 parts by weight or more of Fe based on the total 100 parts by weight of the transition metal. The sputtering target may include 0.03 parts by weight or less of Fe based on the total 100 parts by weight of the transition metal. The sputtering target may include 0.025 parts by weight or less of Fe based on the total 100 parts by weight of the transition metal. In these cases, a degree of charging on the surface of the light-blocking layer due to the electron beam radiation may be decreased, and a light-blocking layer having a stable etching speed with respect to a chlorine-based etchant may be provided.

The content of each element of the sputtering target may be measured and confirmed using inductively coupled plasma-optical emission spectrometry (ICP-OES). For example, the content of each element of the sputtering target may be measured by ICP-OES from Seiko Instruments.

Thickness of the Light-Blocking Layer

The thickness of the first light-blocking layer 21 may range from 250 Å to 650 Å. The thickness of the first light-blocking layer 21 may range from 350 Å to 600 Å. The thickness of the first light-blocking layer 21 may range from 400 Å to 550 Å.

These cases may help the first light-blocking layer 21 to have excellent light extinction characteristics.

The thickness of the second light-blocking layer 22 may range from 30 Å to 200 Å. The thickness of the second light-blocking layer 22 may range from 30 Å to 100 Å. The thickness of the second light-blocking layer 22 may range from 40 Å to 80 Å. In these cases, the resolution of the photomask implemented from the blank mask 100 can be further improved.

A ratio of the thickness of the second light-blocking layer 22 to the thickness of the first light-blocking layer 21 may range from 0.05 to 0.3. The thickness ratio may range from 0.07 to 0.25. The thickness ratio may range from 0.1 to 0.2. In these cases, a lateral shape of the patterned light-blocking layer may be more precisely controlled.

The total thickness of the light-blocking layer 20 may range from 280 Å to 850 Å. The total thickness may range from 380 Å to 700 Å. The total thickness may range from 440 Å to 630 Å. In these cases, sufficient light extinction characteristics may be imparted to the light-blocking layer, and a resist layer with a relatively low thickness may be applied during the patterning of the light-blocking layer.

Optical Characteristics of the Light-Blocking Layer

An optical density of the light-blocking layer 20 with respect to light having a 193 nm wavelength may be 1.3 or more. The optical density of the light-blocking layer 20 with respect to the light having the 193 nm wavelength may be 1.4 or more.

Transmittance of the light-blocking layer 20 with respect to the light having the 193 nm wavelength may be 2% or less. The transmittance of the light-blocking layer 20 with respect to the light having the 193 nm wavelength may be 1.9% or less.

These cases may help the light-blocking layer 20 to effectively block transmission of the exposure light.

The optical density and transmittance of the light-blocking layer 20 may be measured using a spectroscopic ellipsometer. For example, the optical density and transmittance of the light-blocking layer 20 may be measured using an MG-Pro model from NanoView Co., Ltd.

Other Thin Films

FIG. 3 is a conceptual diagram for describing a blank mask according to still another embodiment. The following description will be made with reference to FIG. 3.

The phase inversion layer 30 may be disposed between the light transmissive substrate 10 and the light-blocking layer 20. The phase inversion layer 30 is a thin film for a light intensity of the exposure light passing through the phase inversion layer 30 and substantially suppresses diffracted light generated at an edge of a transfer pattern by adjusting a phase difference of the exposure light.

A phase difference of the phase inversion layer 30 with respect to light having a 193 nm wavelength may range from 170° to 190°. The phase difference of the phase inversion layer 30 with respect to the light having the 193 nm wavelength may range from 175° to 185°.

Transmittance of the phase inversion layer 30 with respect to the light having the 193 nm wavelength may range from 3% to 10%. The transmittance of the phase inversion layer 30 with respect to the light having the 193 nm wavelength may range from 4% to 8%.

In these cases, it is possible to effectively suppress the diffracted light that may occur at the edge of the pattern layer.

An optical density of a thin film including the phase inversion layer 30 and the light-blocking layer 20 with respect to the light having the 193 nm wavelength may be 3 or more. The optical density of the thin film including the phase inversion layer 30 and the light-blocking layer 20 with respect to the light having the 193 nm wavelength may be 5 or less. In these cases, the thin film may effectively suppress the transmission of the exposure light.

The phase difference and transmittance of the phase inversion layer 30 and the optical density of the thin film including the phase inversion layer 30 and the light-blocking layer 20 may be measured using a spectroscopic ellipsometer. For example, an MG-Pro model from NanoView Co., Ltd. may be employed as the spectroscopic ellipsometer.

The phase inversion layer 30 may include a transition metal and silicon. The phase inversion layer 30 may include a transition metal, silicon, oxygen, and nitrogen. The transition metal may be molybdenum.

A hard mask (not shown) may be positioned on the light-blocking layer 20. The hard mask may serve as an etching mask during etching of the pattern of the light-blocking layer 20. The hard mask may include silicon, nitrogen, and oxygen.

A resist layer (not shown) may be positioned on the light-blocking layer. The resist layer may be formed in contact with an upper surface of the light-blocking layer. The resist layer may be formed in contact with an upper surface of another thin film disposed on the light-blocking layer.

The resist layer may form a resist pattern layer through electron beam radiation and development. The resist pattern layer may serve as an etching mask during etching of the pattern of the light-blocking layer 20.

A positive resist may be applied as the resist layer. A negative resist may be applied as the resist layer. For example, an FEP255 model from Fuji Co., Ltd. may be employed as the resist layer.

Photomask

FIG. 4 is a conceptual diagram for describing a photomask according to yet another embodiment. The following description will be made with reference to FIG. 4.

A photomask 200 according to yet another embodiment includes a light transmissive substrate 10 and a light-blocking pattern layer 25 disposed on the light transmissive substrate 10.

The light-blocking pattern layer 25 includes a transition metal and either one or both of oxygen and nitrogen.

An average value of grain sizes of a surface of the light-blocking pattern layer ranges from 14 nm to 24 nm.

Description of the light transmissive substrate 10 included in the photomask 200 overlaps the above description and thus will be omitted.

The light-blocking pattern layer 25 may be formed by patterning the above-described light-blocking layer 20.

Descriptions of a layer structure, physical properties, a composition of the light-blocking pattern layer 25 overlap the above description of the light-blocking layer 20 and thus will be omitted.

Method of Manufacturing Light-Blocking Layer

A method of manufacturing a blank mask according to one embodiment includes a preparation operation of arranging a sputtering target including a transition metal and a light transmissive substrate inside a sputtering chamber, a first light-blocking layer formation operation of forming a first light-blocking layer on the light transmissive substrate, a second light-blocking layer formation operation of forming a light-blocking layer by forming a second light-blocking layer on the first light-blocking layer, and a thermal processing operation of thermally processing the light-blocking layer.

In the preparation operation, a target may be selected when the light-blocking layer is formed in consideration of a composition of the light-blocking layer.

The sputtering target may include 90 wt % or more transition metal. The sputtering target may include 95 wt % or more transition metal. The sputtering target may include 99 wt % or more transition metal.

The transition metal may include at least one among Cr, Ta, Ti, and Hf. The transition metal may include Cr. The transition metal may be Cr.

The sputtering target may further include Fe.

The sputtering target may include 0.0001 wt % or more Fe. The sputtering target may include 0.001 wt % or more Fe. The sputtering target may include 0.003 wt % or more Fe. The sputtering target may include 0.035 wt % or less Fe. The sputtering target may include 0.03 wt % or less Fe. The sputtering target may include 0.025 wt % or less Fe.

The sputtering target may include 0.0001 parts by weight or more of Fe based on the total 100 parts by weight of the transition metal. The sputtering target may include 0.001 parts by weight or more of Fe based on the total 100 parts by weight of the transition metal. The sputtering target may include 0.003 parts by weight or more of Fe based on the total 100 parts by weight of the transition metal. The sputtering target may include 0.035 parts by weight or less of Fe based on the total 100 parts by weight of the transition metal. The sputtering target may include 0.03 parts by weight or less of Fe based on the total 100 parts by weight of the transition metal. The sputtering target may include 0.025 parts by weight or less of Fe based on the total 100 parts by weight of the transition metal.

In these cases, a grain boundary density of the light-blocking layer formed by applying the sputtering target may be adjusted to reduce the degree of electron accumulation on the surface of the light-blocking layer due to electron beam radiation. Simultaneously, a decrease in the etching speed of the light-blocking layer due to the growth of crystal grains can be suppressed.

The content of each element of the sputtering target may be measured and confirmed using ICP-OES. For example, the content of each element of the sputtering target may be measured by ICP-OES from Seiko Instruments.

In the preparation operation, a magnet may be disposed in the sputtering chamber. The magnet may be disposed on a surface opposite to a surface on which sputtering occurs in the sputtering target.

In the first light-blocking layer formation operation and the second light-blocking layer formation operation, different sputtering process conditions may be applied to layers included in the light-blocking layer. Specifically, in consideration of grain boundary distribution characteristics, etching characteristics, and extinction characteristics desired for the layers, different process conditions such as a composition of an atmospheric gas, power applied to the sputtering target, and a formation time may be applied to the layers.

The atmospheric gas may include an inert gas and a reactive gas. The inert gas is a gas not containing elements constituting the formed thin film. The reactive gas is a gas containing elements constituting the formed thin film.

The inert gas may include a gas that is ionized in a plasma atmosphere and collides with the sputtering target. The inert gas may include Ar. The inert gas may further include He for the purpose of stress control of a thin film to be formed.

The reactive gas may include a gas containing the element nitrogen. Examples of the gas containing the element nitrogen may include N₂, NO, NO₂, N₂O, N₂O₃, N₂O₄, and N₂O₅ gases. The reactive gas may include a gas containing the element oxygen. Examples of the gas containing the element oxygen may include O₂ and CO₂ gases. The reactive gas may include a gas containing the element nitrogen and a gas containing the element oxygen.

The reactive gas may include a gas containing both the element nitrogen and the element oxygen. Examples of the gas containing both the element nitrogen and the element oxygen may include NO, NO₂, N₂O, N₂O₃, N₂O₄, and N₂O₅ gases.

A DC power source or a radio frequency (RF) power source may be employed as a power source for applying power to the sputtering target.

In the first light-blocking layer formation operation, power applied to the sputtering target may be 1.5 kW or more and 2.5 kW or less. The power applied to the sputtering target may be 1.6 kW or more and 2 kW or less.

In the first light-blocking layer formation operation, a ratio of a flow rate of the reactive gas to a flow rate of the inert gas in the atmospheric gas may be 0.5 or more. The flow rate ratio may be 0.7 or more. The flow rate ratio may be 1.5 or less. The flow rate ratio may be 1.2 or less. The flow rate ratio may be 1 or less.

In the atmosphere gas, a ratio of a flow rate of Ar gas to the total flow rate of the inert gas may be 0.2 or more. The flow rate ratio may be 0.25 or more. The flow rate ratio may be 0.3 or more. The flow rate ratio may be 0.55 or less. The flow rate ratio may be 0.5 or less.

In the atmospheric gas, a ratio of oxygen content to nitrogen content included in the reactive gas may be 1.5 or more and 4 or less. The ratio may be 1.8 or more and 3.8 or less. The ratio may be 2 or more and 3.5 or less.

In these cases, the formed first light-blocking layer may help the light-blocking layer to have sufficient light extinction characteristics. In addition, the formed first light-blocking layer may help to control a precise shape of the light-blocking pattern layer during the light-blocking layer patterning operation.

The formation of the first light-blocking layer may be performed for a time of 200 seconds or more and 300 seconds or less. The formation of the first light-blocking layer may be performed for a time of 230 seconds or more and 280 seconds or less. In these cases, the formed first light-blocking layer may help the light-blocking layer to have sufficient light extinction characteristics.

In the second light-blocking layer formation operation, power applied to the sputtering target may be 1 kW or more and 2 kW or less. The power ranging from 1.2 kW to 1.7 kW may be applied. These cases may help the second light-blocking layer have desired optical characteristics and etching characteristics.

The second light-blocking layer formation operation may be performed with an interval of 15 seconds or more immediately after the formation of a thin film (e.g., the first light-blocking layer) disposed in contact with a lower surface of the second light-blocking layer. The second light-blocking layer formation operation may be performed with an interval of 20 seconds or more immediately after the formation of the thin film disposed in contact with the lower surface of the second light-blocking layer. The second light-blocking layer formation operation may be performed within an interval of 30 seconds immediately after the formation of the thin film disposed in contact with the lower surface of the second light-blocking layer.

The second light-blocking layer forming operation may be performed after completely exhausting the atmospheric gas applied to the formation of the thin film (e.g., the first light-blocking layer) disposed in contact with the lower surface of the second light-blocking layer from the sputtering chamber. The second light-blocking layer formation operation may be performed within 10 seconds from a time point when the atmospheric gas applied to the formation of the thin film disposed in contact with the lower surface of the second light-blocking layer is completely exhausted. The second light-blocking layer formation operation may be performed within 5 seconds from the time point when the atmospheric gas applied to the formation of the thin film disposed in contact with the lower surface of the second light-blocking layer is completely exhausted.

In these cases, the composition of the second light-blocking layer may be more precisely controlled.

In the second light-blocking layer formation operation, the ratio of the flow rate of the reactive gas to the flow rate of the inert gas included in the atmospheric gas may be 0.4 or more. The flow rate ratio may be 0.5 or more. The flow rate ratio may be 0.65 or more. The flow rate ratio may be 1 or less. The flow rate ratio may be 0.9 or less.

In the atmosphere gas, a ratio of a flow rate of Ar gas to the total flow rate of the inert gas may be 0.8 or more. The flow rate ratio may be 0.9 or more. The flow rate ratio may be 0.95 or more. The flow rate ratio may be 1 or less.

In the second light-blocking layer formation operation, a ratio of oxygen content to nitrogen content included in the reactive gas may be 0.3 or less. The ratio may be 0.1 or less. The ratio may be 0.001 or more. The ratio may be 0 or more.

These cases may help to control the grain-related characteristics of the surface of the light-blocking layer within a previously set range in the embodiment.

The formation of the second light-blocking layer may be performed for a time of 10 seconds or more and 30 seconds or less. The formation of the second light-blocking layer may be performed for a time of 15 seconds or more and 25 seconds or less. In these cases, when the light-blocking pattern layer is formed through dry etching, the shape of the light-blocking pattern layer may be more precisely controlled.

In the thermal processing operation, the light-blocking layer may be thermally processed. A substrate on which the light-blocking layer is formed is disposed in the thermal processing chamber, and then the light-blocking layer may be thermally processed. According to the embodiment, the internal stress of the light-blocking layer may be decreased by performing the thermal processing operation on the formed light-blocking layer, and the size of a crystal grain formed through recrystallization may be adjusted.

In the thermal processing operation, an atmospheric temperature in the thermal processing chamber may be 150° C. or more. The atmospheric temperature may be 200° C. or more. The atmospheric temperature may be 250° C. or more. The atmospheric temperature may be 400° C. or less. The atmospheric temperature may be 350° C. or less.

The thermal processing operation may be performed for 5 minutes or more. The thermal processing operation may be performed for 10 minutes or more. The thermal processing operation may be performed for 60 minutes or less. The thermal processing operation may be performed for 45 minutes or less. The thermal processing operation may be performed for 25 minutes or less.

In these cases, a degree of growth of crystal grains in the light-blocking layer may be controlled to help the surface of the light-blocking layer to have grain size and roughness characteristics within a previously set range in the embodiment, and internal stress of the light-blocking layer may be effectively removed.

The method of manufacturing a blank mask according to the embodiment may further include a cooling operation of cooling the thermally processed light-blocking layer. In the cooling operation, a cooling plate may be installed on the light transmissive substrate to cool the light-blocking layer.

A separation distance between the light transmissive substrate and the cooling plate may be 0.05 mm or more and 2 mm or less. The cooling temperature of the cooling plate may be 10° C. or more and 40° C. or less. The cooling operation may be performed for 5 minutes or more and 20 minutes or less.

In these cases, the continued growth of crystal grains due to residual heat in the thermally processed light-blocking layer may be effectively suppressed.

Method of Manufacturing Semiconductor Device

A method of manufacturing a semiconductor device according to another embodiment includes a preparation operation of arranging a light source and a semiconductor wafer on which a photomask and a resist layer are applied, an exposure operation of selectively transmitting and emitting light incident from the light source through the photomask to the semiconductor wafer, and a development operation of developing a pattern on the semiconductor wafer.

The photomask includes a light-transmissive substrate and a light-blocking pattern layer disposed on the light-transmissive substrate.

The light-blocking pattern layer includes a transition metal and either one or both of oxygen and nitrogen.

The average value of grain sizes of a surface of the light-blocking pattern layer ranges from 14 nm to 24 nm.

In the preparation operation, the light source is a device capable of generating exposure light of a short wavelength. The exposure light may be light with a wavelength of 200 nm or less. The exposure light source may be ArF light with a 193 nm wavelength.

A lens may be additionally disposed between the photomask and the semiconductor wafer. The lens has a function of reducing a circuit pattern shape on the photomask and transferring the reduced circuit pattern shape onto the semiconductor wafer. The lens is not limited as long as it can be generally applied to an ArF semiconductor wafer exposure process. For example, a lens made of calcium fluoride (CaF₂) may be employed as the lens.

In the exposure operation, the exposure light may be selectively transmitted onto the semiconductor wafer through the photomask. In this case, chemical degeneration may occur in a portion of the resist layer on which the exposure light is incident.

In the development operation, the pattern may be developed on the semiconductor wafer by processing the semiconductor wafer that has undergone the exposure operation with a developer. When the applied resist layer is a positive resist, the portion of the resist layer on which the exposure light is incident may be dissolved by the developer. When the applied resist layer is a negative resist, a portion of the resist layer on which the exposure light is not incident may be dissolved by the developer. The resist layer is formed into a resist pattern by a process using the developer. A pattern may be formed on the semiconductor wafer using the resist pattern as a mask.

A description of the photomask overlaps the above-described content and thus will be omitted.

Hereinafter, specific examples will be described in more detail.

### Manufacturing Examples: Formation of Light-Blocking Layer

Example 1: A light transmissive substrate made of quartz with 6 inches horizontally, 6 inches vertically, a thickness of 0.25 inches, and a flatness of less than 500 nm was disposed in a chamber of a DC sputtering device. A sputtering target having a composition shown in the following Table 1 was disposed in the chamber so that a T/S distance was 255 mm and an angle between the substrate and the target was 25 degrees. A magnet was installed on a rear surface of the sputtering target.

Thereafter, an atmospheric gas, in which 19 vol % Ar, 11 vol % N₂, 36 vol % CO₂, and 34 vol % He were mixed, was introduced into the chamber, and a first light-blocking layer was formed by performing a sputtering process for 250 seconds by applying power of 1.85 kW to the sputtering target and a magnet rotation speed of 113 rpm.

After the formation of the first light-blocking layer was completed, an atmosphere gas, in which 57 vol % Ar and 43 vol % N₂ were mixed, was introduced onto the first light-blocking layer in the chamber, and a second light-blocking layer was formed by performing a sputtering process for 250 seconds by applying power of 1.85 kW to the sputtering target and a magnet rotation speed of 113 rpm.

A sample on which the formation of the second light-blocking layer was completed was disposed in a thermal processing chamber. Thereafter, thermal processing was performed for 15 minutes by applying an ambient temperature of 250° C.

A cooling plate, to which a cooling temperature ranging from 10° C. to 40° C. was applied, was installed on the substrate of a blank mask that had undergone the thermal processing process, and then cooling processing was performed. A distance between the substrate of the blank mask and the cooling plate was set to 0.1 mm. The cooling processing was performed for 5 to 20 minutes.

Example 2: A sample of a blank mask was manufactured under the same conditions, as in Example 1, except that a sputtering target was disposed as a target having a composition shown in the following Table 1 in the preparation operation, and an ambient temperature of 300° C. was applied in the thermal processing operation.

Examples 3 to 5 and Comparative Examples 1 to 3: Samples of blank masks were manufactured under the same conditions, as in Example 1, except that a sputtering target was disposed as a target having a composition shown in the following Table 1 in the preparation operation.

The composition of the sputtering target applied for each example and a comparative example is shown in the following Table 1.

### Evaluation Example: Grain-Related Measurement

An average value of grain sizes and the number of grains per unit area of the surface of the light-blocking layer for each example and comparative example were measured through SEM.

Specifically, measurement magnification of the SEM was set to 150 k, a voltage to 5.0 kV, and a WD to 4 mm, and an image of the surface of the light-blocking layer was measured. The average value of the grain sizes of the surface of the light-blocking layer was measured from the image through an intercept method disclosed in ASTM E112-96e1.

In addition, the number of grains in an area of 1 μm horizontally and 1 μm vertically in the SEM image was measured. When the number of grains was calculated, grains located across one side of the area of 1 μm horizontally and 1 μm vertically were calculated as 0.5, and grains located across a corner of the area and only partially observed were calculated as 0.25.

The measured results for each example and comparative example are shown in the following Table 2.

### Evaluation Example: Evaluation of Whether Light-Blocking Pattern Layer is Defective

After the resist layer was on the upper surface of the light-blocking layer of the sample for each example and comparative example, contact hole patterns were formed in a central portion of the resist layer using an electron beam. The contact hole patterns consisted of a total of 156 contact hole patterns formed 13 in a horizontal direction and 12 in a vertical direction. The diameter of each contact hole pattern was set to a range from 60 nm to 80 nm.

Then, an image of a surface of the patterned resist layer for each sample was measured. A case in which the number of resist contact hole patterns detected as defects for each sample was 6 or more was evaluated as F (resist).

Patterning was performed on the light-blocking layer for each sample not evaluated as F (resist). Then, the patterned resist layer was removed, and then an image of the surface of the patterned light-blocking layer was measured. A case in which the number of light-blocking layer contact hole patterns detected as defects for each sample was 6 or more was evaluated as F (light-blocking layer), whereas, a case in which the number of light-blocking layer contact hole patterns detected as defects for each sample was 5 or less was evaluated as P.

The measured results for each example and comparative example are shown in the following Table 2.

### Evaluation Example: Measurement of Etching Characteristics of Light-Blocking Layer

Two samples of Example 1 were each processed into a size of 15 mm horizontally and 15 mm vertically. A surface of the processed sample was processed with an FIB and placed in a JEM-2100F HR model from JEOL Ltd., and a TEM image of the sample was measured. Thicknesses of the first light-blocking layer and the second light-blocking layer were calculated from the TEM image.

Then, with respect to one sample of Example 1, the time desired for etching the first light-blocking layer and the second light-blocking layer with Ar gas was measured. Specifically, the sample was placed in a K-Alpha model from Thermo Fisher Scientific Inc., and an area of 4 mm horizontally and 2 mm vertically positioned in a central portion of the sample was etched with Ar gas to measure an etch time for each layer. When the etch time was measured for each layer, a vacuum level in the measuring instrument equipment was set to 1.0*10⁻⁸ mbar, an X-ray source was Monochromator Al Kα (1486.6 eV), anode power was set to 72 W, an anode voltage was set to 12 kV, and a voltage of an Ar ion beam was set to 1 kV.

An etching speed for each layer was calculated from the measured thicknesses and etching times of the first light-blocking layer and the second light-blocking layer.

The other sample of Example 1 was etched with a chlorine-based gas to measure the time desired for etching the entirety of the light-blocking layer. A gas containing 90 vol % to 95 vol % chlorine gas and 5 vol % to 10 vol % oxygen gas was employed as the chlorine-based gas. An etching speed of the light-blocking layer for the chlorine-based gas was calculated from the thickness and etching time of the light-blocking layer.

Measured values of the etching speeds for Ar gas and the chlorine-based gas in Example 1 are shown in the following Table 3.

### Evaluation Example: Composition Measurement for Each Layer

The content of each element in each layer in the light-blocking layers of Example 1 and Comparative Example 1 was measured using XPS analysis. Specifically, samples were prepared by processing each of the blank masks of Example 1 and Comparative Example 1 into a size of 15 mm horizontally and 15 mm vertically. After the sample was placed in the K-Alpha model measuring instrument from Thermo Fisher Scientific Inc., an area of 4 mm horizontally and 2 mm vertically positioned in a central portion of the specimen was etched to measure the content of each element in each layer. The measured results for each example and comparative example are shown in the following Table 4.

TABLE 1

| | Content for each element of the sputtering target | | | | | |
|---|---|---|---|---|---|---|
| | Cr | C | O | N | Fe | |
| | (wt %) | (wt %) | (wt %) | (wt %) | (wt %) | weight (g) |
| Example 1 | 99.985 | 0.002 | 0.009 | 0.001 | 0.003 | 0.040 |
| Example 2 | 99.985 | 0.002 | 0.009 | 0.001 | 0.003 | 0.040 |
| Example 3 | 99.983 | 0.002 | 0.009 | 0.001 | 0.005 | 0.067 |
| Example 4 | 99.988 | 0.001 | 0.009 | 0.001 | 0.001 | 0.013 |
| Example 5 | 99.978 | 0.002 | 0.009 | 0.001 | 0.010 | 0.134 |
| Comparative | 99.988 | 0.002 | 0.009 | 0.001 | 0.000 | 0.000 |
| Example 1 | | | | | | |
| Comparative | 99.948 | 0.002 | 0.009 | 0.001 | 0.040 | 1.073 |
| Example 2 | | | | | | |
| Comparative | 99.908 | 0.003 | 0.008 | 0.001 | 0.080 | 1.073 |
| Example 3 | | | | | | |

TABLE 2

| | Average value | Number of | Evaluation of whether |
|---|---|---|---|
| | of grain | grains per | light-blocking pattern |
| | sizes (nm) | 0.01 μm² | layer is defective |
| Example 1 | 17.65 | 33.5 | P |
| Example 2 | 17.91 | 32.5 | P |
| Example 3 | 16.22 | 40 | P |
| Example 4 | 21.82 | 22 | P |
| Example 5 | 14.63 | 49 | P |
| Comparative | 24.49 | 17.5 | F (light-blocking |
| Example 1 | | | layer) |
| Comparative | 13.19 | 60 | F (resist) |
| Example 2 | | | |
| Comparative | 11.76 | 75.5 | F (resist) |
| Example 3 | | | |

TABLE 3

| | Measured etching | Measured etching | Measured etching |
|---|---|---|---|
| | speed (Å/s) of | speed (Å/s) of | speed (Å/s) of |
| | first light-block- | second light-block- | light-blocking |
| | ing layer etched | ing layer etched | layer etched with |
| | with Ar gas | with Ar gas | chlorine-based gas |
| Example 1 | 0.621 | 0.430 | 1.7 |

TABLE 4

| | | Cr (at %) | C (at %) | N (at %) | O (at %) |
|---|---|---|---|---|---|
| Example 1 | Second | 57.4 | 10.9 | 16.0 | 15.7 |
| | light- | | | | |
| | blocking | | | | |
| | layer | | | | |
| | First light- | 39.3 | 14.9 | 9.7 | 36.1 |
| | blocking | | | | |
| | layer | | | | |
| Comparative | Second | 57.2 | 10.5 | 16.3 | 15.9 |
| Example 1 | light- | | | | |
| | blocking | | | | |
| | layer | | | | |
| | First light- | 39.6 | 14.7 | 9.4 | 36.3 |
| | blocking | | | | |
| | layer | | | | |

In the evaluation of whether the light-blocking pattern layer is defective, Examples 1 to 5 were evaluated as P, whereas, Comparative Examples 1 to 3 were evaluated as F.

In Table 3, each measured value of the etching speed of Example 1 was measured to be included within a range limited by the embodiment.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A blank mask comprising:
a light transmissive substrate; and
a light-blocking layer, disposed on the light transmissive substrate, comprising a transition metal and either one or both of oxygen and nitrogen,
wherein an average value of grain sizes of a surface of the light-blocking layer ranges from 14 nm to 24 nm.

2. The blank mask of claim 1, wherein a number of grains on the surface of the light-blocking layer is 20 or more and 55 or less per 0.01 μm².

3. The blank mask of claim 1, wherein
the light-blocking layer further includes a first light-blocking layer and a second light-blocking layer disposed on the first light-blocking layer, and
an etching speed of the second light-blocking layer etched with argon gas is 0.3 Å/s or more and 0.5 Å/s or less.

4. The blank mask of claim 1, wherein
the light-blocking layer includes a first light-blocking layer and a second light-blocking layer disposed on the first light-blocking layer, and
an etching speed of the first light-blocking layer etched with argon gas is 0.56 Å/s or more.

5. The blank mask of claim 1, wherein an etching speed of the light-blocking layer etched with a chlorine-based gas is 1.5 Å/s or more.

6. The blank mask of claim 1, wherein the transition metal includes Fe and any one or more among Cr, Ta, Ti, and Hf.

7. The blank mask of claim 6, wherein the light-blocking layer is formed using a sputtering target including 0.0001 to 0.035 parts by weight of Fe based on a total of 100 parts by weight of the transition metal.

8. The blank mask of claim 1, wherein
the light-blocking layer further includes a first light-blocking layer and a second light-blocking layer disposed on the first light-blocking layer, and
the second light-blocking layer includes 40 at % or more and 70 at % or less transition metal.

9. A photomask comprising:
a light transmissive substrate; and
a light-blocking pattern layer, disposed on the light transmissive substrate, comprising a transition metal and either one or both of oxygen and nitrogen,
wherein an average value of grain sizes of a surface of the light-blocking pattern layer ranges from 14 nm to 24 nm.

10. A method of manufacturing a semiconductor device, comprising:
selectively exposing light incident from a light source through a photomask to a semiconductor wafer on which a resist layer is deposited; and
developing a pattern on the semiconductor wafer,
wherein the photomask includes a light transmissive substrate and a light-blocking pattern layer disposed on the light transmissive substrate,
the light-blocking pattern layer includes a transition metal and either one or both of oxygen and nitrogen, and
an average value of grain sizes of a surface of the light-blocking pattern layer ranges from 14 nm to 24 nm.

11. The method of claim 10, wherein the light-blocking layer further includes a plurality of light-blocking layers, and
an etching speed of a topmost light-blocking layer of the plurality of light-blocking layers etched with argon gas is 0.3 Å/s or more and 0.5 Å/s or less.

12. The method of claim 10, wherein the light-blocking layer further includes a plurality of light-blocking layers, and
an etching speed of an intermediate light-blocking layer of the plurality of light-blocking layers etched with argon gas is 0.56 Å/s or more.
